(19) United States
(12) Patent Application Publication
(10) Pub. No.: US 2026/0339152 A1
(43) Pub. Date: Oct. 29, 2026

(54) PLANAR LIGHTING DEVICE AND DISPLAY DEVICE USING SAME

(71) Applicant: LG ELECTRONICS INC., Seoul (KR)

(72) Inventors: Jaehyeok Kim, Seoul (KR); Jeoungoun Lee, Seoul (KR); Sehoon Jeong, Seoul (KR)

(73) Assignee: LG ELECTRONICS INC., Seoul (KR)

(21) Appl. No.: 19/353,133

(22) Filed: Oct. 8, 2025

(30) Foreign Application Priority Data
Apr. 29, 2025 (KR) 10-2025-0055963

(51) Int. Cl. G02F 1/1335; G02F 1/13357

(52) U.S. Cl. CPC G02F 1/133614; G02F 1/133606

(57) ABSTRACT

A planar lighting device including a wiring board, a light source including a plurality of first and second light-emitting device packages disposed on the wiring board, and a light diffusion layer. Each first light-emitting device package includes a first light-emitting device emitting light of a first wavelength band of a first color and a second wavelength band a second color, and a first phosphor converting light emitted from the first light-emitting device to a third wavelength band of a third color. Each second light-emitting device package includes a second light-emitting device emitting light of a fourth wavelength band of the first color, a second phosphor converting light emitted from the second light-emitting device to a fifth wavelength band of the third color; and a third phosphor converting light emitted from the second light-emitting device to a sixth wavelength band of the third color.

### CROSS-REFERENCE TO RELATED APPLICATIONS

The present application claims priority under 35 U.S.C. § 119 and 35 U.S.C. § 365 to Korean Patent Application No. 10-2025-0055963, filed on Apr. 29, 2025, which is hereby incorporated by reference in its entirety.

### BACKGROUND

### 1. Technical Field

The present disclosure is related to display devices including, for example, a planar lighting device and a display device using a light-emitting device package.

### 2. Description of Related Art

Display devices having excellent characteristics such as thinness, flexibility, etc., are being developed in the fields of display technologies. The major displays currently commercialized include liquid crystal displays (LCDs) and organic light-emitting diodes (OLEDs). Of these displays, the liquid crystal display devices (LCDs) are used in a variety of devices including televisions, laptop computers, desktop computer monitors, and mobile phones.

Because the LCDs do not emit light by themselves, a light-emitting device capable of illuminating a liquid crystal panel is used to display image information. Because the light-emitting device of the LCD is connected to a rear surface of the liquid crystal panel, the light-emitting device can be called a planar lighting device or a backlight unit. In particular, the backlight unit forms a uniform surface light source to provide uniform light to the liquid crystal panel. The backlight unit as described above can also be considered an example of the planar lighting device because the backlight unit provides a planar light source toward the liquid crystal panel. In particular, the planar lighting device is recognized as a light source that is capable of evenly irradiating light through a flat surface and has a relatively thin thickness. Further, the light emitting device such as the light emitting diode is used as the light source for the planar lighting device. To implement a white light source in the light-emitting device, a blue light emitting device and a phosphor may be used in combination. For example, the blue light emitting device and a yellow phosphor can be combined to implement the white light source.

### SUMMARY OF THE DISCLOSURE

The technical problem to be solved by the present disclosure is to provide a planar lighting device and display device capable of improving color reproducibility, light efficiency while implementing high color reproducibility and implementing a consistent color reproducibility in panels having different characteristics.

In an aspect of the present disclosure, a planar lighting device can include a wiring board, a light source including a plurality of first light-emitting device packages, a plurality of second light-emitting device packages disposed on the wiring board, and a light diffusion layer disposed on the light source. The first light-emitting device package includes a first light-emitting device including a first light-emitting layer having a first wavelength band emitting light of a first color, a second light-emitting layer having a second wavelength band emitting light of a second color, and a first phosphor having a third light-emitting wavelength band converted by light emitted from the first light-emitting device to emit light of a third color. The second light-emitting device package includes a second light-emitting device including a third light-emitting layer having a fourth wavelength band emitting light of the first color, a second phosphor having a fifth wavelength band converted by light emitted from the second device emitting light of the second color. and a third phosphor having a sixth wavelength band converted by light emitted from the second light-emitting device to emit light of the third color.

In an example, a half-width of the spectrum of the first wavelength band can be narrower than a half-width of the spectrum of the fourth wavelength band. In another example, an intensity of the spectrum of the first wavelength band can be smaller than an intensity of the spectrum of the fourth wavelength band. In yet another example, a half-width of the spectrum of the fifth wavelength band can be narrower than a half-width of the spectrum of the second wavelength band.

In an example, an intensity of the spectrum of the fifth wavelength band can be smaller than an intensity of the spectrum of the second wavelength band. In another example, the first light-emitting device package and the second light-emitting device package can have different color coordinate settings. In yet another example, the first light-emitting device package and the second light-emitting device package can be disposed adjacent to each other.

In another example, a shift in a color coordinate of the second light-emitting device package according to current can be smaller than a shift in a color coordinate of the first light-emitting device package according to current. In an example, the first light-emitting device package can include a first-1 light-emitting device and a first-2 light-emitting device adjacent to each other. In another example, the first-1 light-emitting device and the first-2 light-emitting device can have different stacking orders of the first light-emitting layer and the second light-emitting layer.

In another aspect of the present disclosure, a display device can include a planar lighting device emitting white light, and a liquid crystal display panel disposed on the planar lighting device and having a color conversion filter for converting the white light of the planar lighting device. The planar lighting device can include a light source including a plurality of first light-emitting device packages, a plurality of second light-emitting device packages constituting a white light source, and a light diffusion layer disposed on the light source. The first light-emitting device package includes a first light-emitting device including a first light-emitting layer having a first wavelength band emitting light of a first color and a second light-emitting layer having a second wavelength band emitting light of a second color, and a first phosphor having a third wavelength band converted by light emitted from the first light-emitting device to emit light of a third color. The second light-emitting device package includes a second light-emitting device including a third light-emitting layer having a fourth wavelength band emitting light of the first color, a second phosphor having a fifth wavelength band converted by light emitted from the second light-emitting device to emit light of the second color. and a third phosphor having a sixth wavelength band converted by light emitted from the second light-emitting device to emit light of the third color.

In an example, a content of at least one of the second phosphor or the third phosphor of the second light-emitting device package can be adjusted according to a transmission spectrum of the color conversion filter. In another example, the second phosphor can have a first content to have a target color coordinate value of the liquid crystal display panel. In yet another example, the third phosphor can have a second content to have a target color coordinate value of the liquid crystal display panel.

In still another aspect of the present disclosure, a display device can include a planar lighting device emitting white light, a liquid crystal display panel disposed on the planar lighting device, and a color conversion filter for converting the white light of the planar lighting device with the planar lighting device including a light source including a plurality of light-emitting device packages constituting a white light source and a light diffusion layer disposed on the light source. The light-emitting device packages includes a light-emitting device including a first light-emitting layer having a first wavelength band emitting light of a first color, a second light-emitting layer having a second wavelength band emitting light of a second color, and a phosphor having a third wavelength band converted by light emitted from the light-emitting device and emits light of a third color.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a conceptual diagram of a planar lighting device according to a first embodiment of the present disclosure.

FIG. 2 is a cross-sectional schematic diagram illustrating an example of a first light-emitting device package applied to a planar lighting device according to a first embodiment of the present disclosure.

FIG. 3 is a cross-sectional schematic diagram illustrating another example of a light-emitting device package applied to a planar lighting device according to a first embodiment of the present disclosure.

FIG. 4 is a cross-sectional schematic diagram illustrating a first light-emitting device applied to a planar lighting device according to a first embodiment of the present disclosure.

FIG. 5 is a cross-sectional schematic diagram illustrating an example of a second light-emitting device package applied to a planar lighting device according to a first embodiment of the present disclosure.

FIG. 6 is a cross-sectional schematic diagram showing an example of a second light-emitting device applied to a planar lighting device according to a first embodiment of the present disclosure.

FIG. 7 is a cross-sectional schematic diagram showing another example of a second light-emitting device applied to a planar lighting device according to a first embodiment of the present disclosure.

FIG. 8 is a diagram showing the emission spectrum of a first light-emitting device package applied to a planar lighting device according to a first embodiment of the present disclosure.

FIG. 9 is a diagram showing the emission spectrum of a second light-emitting device package applied to a planar lighting device according to a first embodiment of the present disclosure.

FIG. 10 is a conceptual diagram of a planar lighting device according to a second embodiment of the present disclosure.

FIG. 11 is a conceptual diagram of a planar lighting device according to a third embodiment of the present disclosure.

FIG. 12 is a schematic diagram illustrating a process of tuning a target color coordinate of the display device using the planar lighting device according to the second or third embodiment of the present disclosure.

FIG. 13 is a schematic diagram illustrating a process of tuning a target color coordinate of the display device using the planar lighting device according to the first embodiment of the present disclosure.

FIGS. 14-19 are cross-sectional schematic diagrams illustrating another embodiments of the first light-emitting device package applied to the planar lighting device according to the embodiments of the present disclosure.

FIGS. 20 and 21 are diagrams illustrating differences according to the stacking order of the first light-emitting device package applied to the planar lighting device according to embodiments of the present disclosure.

FIG. 22 is a diagram illustrating a wavelength change according to a driving current of the first light-emitting device package applied to the planar lighting device according to embodiments of the present disclosure.

FIG. 23 is a diagram illustrating the emission spectrum of the display device according to the embodiments of the present disclosure.

FIGS. 24 and 25 are diagrams illustrating a display device according to a first embodiment of the present disclosure.

FIGS. 26 and 27 are diagrams illustrating a display device according to a second embodiment of the present disclosure.

### DETAILED DESCRIPTION OF THE EMBODIMENTS

Hereinafter, embodiments disclosed in this specification is described with reference to the accompanying drawings, and the same or corresponding components are given with the same drawing number regardless of reference number, and their duplicated description will be omitted. The suffixes “module” and “part” for components used in the description below are assigned or mixed in consideration of easiness in writing the specification and do not have distinctive meanings or roles by themselves. In addition, it should be noted that the attached drawings are only intended to facilitate easy understanding of the embodiments disclosed in this specification, and should not be construed as limiting the technical ideas disclosed in this specification by the attached drawings.

Furthermore, although each drawing is described for convenience of explanation, it is also within the scope of the present disclosure for those skilled in the art to implement another embodiment by combining at least two or more drawings. In addition, in the following description, it will be understood that when a device such as a layer, a region, or substrate is referred to as being “on” another layer, region, or substrate, it can be directly on the other layer, region, or substrate, or intervening layers, regions, or substrates can also be present.

A display device described in this specification is a concept including all display devices that display information as a unit pixel or a set of unit pixels. Therefore, it can be applied not only to finished products but also to parts. For example, a panel, which is a component of a digital TV, is also considered the display device under this specification. The finished products can include mobile phones, smart phones, laptop computers, digital broadcasting terminals, personal digital assistants (PDAs), portable multimedia players (PMPs), navigation systems, slate PCs, tablet PCs, ultra books, digital TVs, and desktop computers. However, those skilled in the art will readily recognize a configuration according to the embodiments described herein can be applied to devices capable of displaying, even if they are new product types developed in the future. In addition, the semiconductor light-emitting device mentioned in the specification is a concept including LEDs, mini-LEDs, micro-LEDs, and the like, and can be used interchangeably.

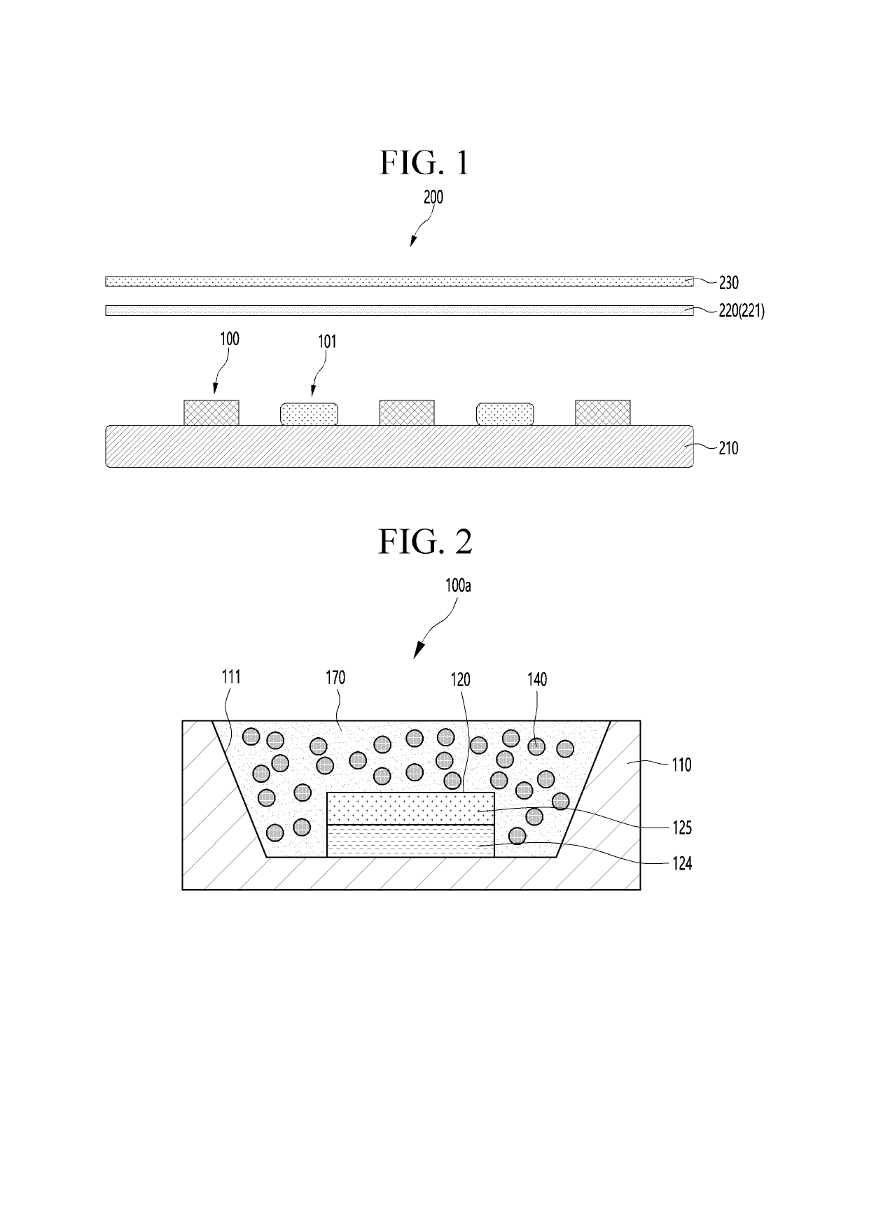

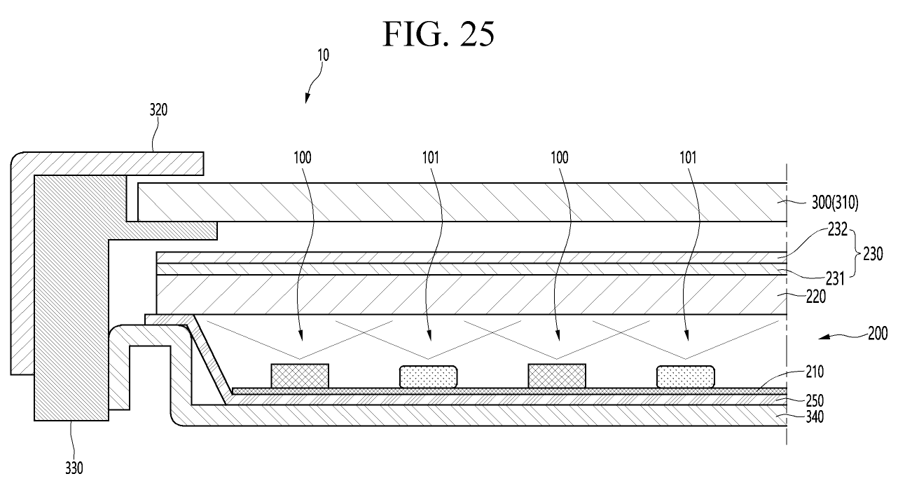

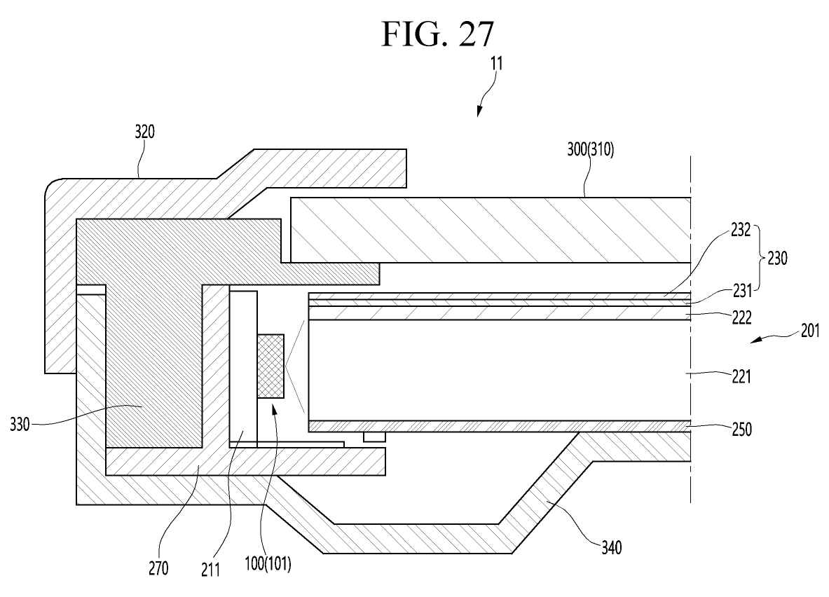

FIG. 1 is a conceptual diagram of a planar lighting device 200 according to a first embodiment of the present disclosure. Referring to FIG. 1, the planar lighting device 200 can be used as a backlight unit providing a flat light source toward a liquid crystal panel 300 and 301 (see FIGS. 25 and 27), and thus can be considered an example of a planar lighting device. Such a planar lighting device can refer to a light source that can uniformly irradiating light through a flat surface and has a relatively thin thickness. Hereinafter, the planar lighting device 200 and the backlight unit 200 will be described interchangeably using the same reference numeral.

As shown in FIG. 1, the planar lighting device 200 includes a wiring board 210, a light source including a plurality of first light-emitting device packages 100 and a plurality of second light-emitting device packages 101 arranged and positioned on the wiring board 210, and a light diffusion layer 220 (221) positioned on the light source. Here, the light diffusion layer 220 (221) can be implemented as a light diffusion plate 220 or a light guide plate 221 depending on the shape of the backlight unit 200.

In addition, an optical sheet 230 can be positioned on one side of the light diffusion layer 220 (221). For instance, the light diffusion layer 220 (221) can be positioned between the wiring board 210 and the optical sheet 230. Also, the optical sheet 230 can include a plurality of layers having optical functions. As shown in FIG. 1, the first light-emitting device package 100 and the second light-emitting device package 101 can be arranged and provided on the wiring board 210. The light-emitting device packages 100 and 101 can emit white light, and can be positioned at a regular interval on the wiring board 210.

In various examples, the wiring board 210 can include a connection wiring electrically connected to the first light-emitting device packages 100 and the second light-emitting device packages 101. For example, at least some of the first light-emitting device packages 100 and the second light-emitting device packages 101 can be individually driven. In other examples, the light sources can be driven simultaneously, or can be driven differently by dividing them according to regions. In this way, a form in which the light sources are driven differently by dividing them into regions can be referred to as local dimming driving.

In addition, as shown in FIGS. 1-4, the first light-emitting device package 100 (110a, 110b) can include a stacked first light-emitting device 120/120a having two light-emitting layers 124 and 125. The first light-emitting device package 100 (100a, 110b) can emit white light having a first color coordinate by including the first light-emitting device 120/120a and a phosphor 140 (a first phosphor) excited by light emitted from the first light-emitting device 120/120a. This will be described in detail below.

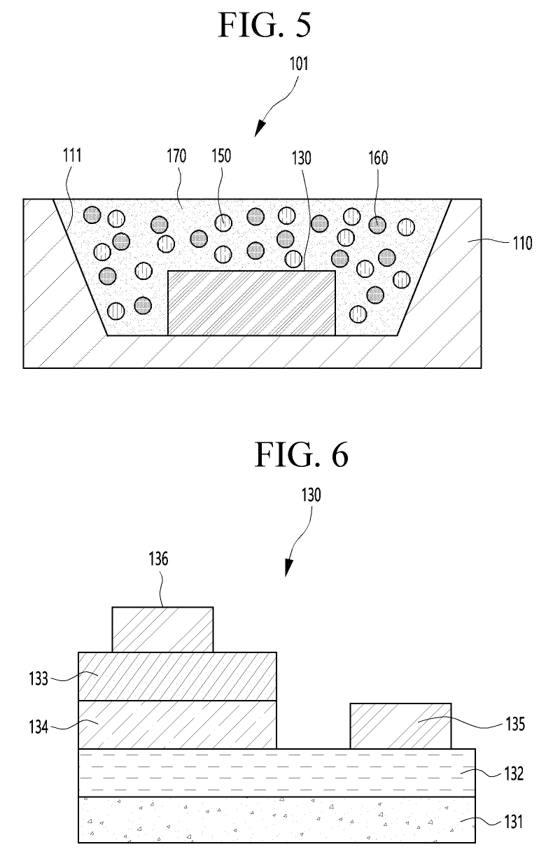

Also, as shown in FIGS. 1 and 5-7, the second light-emitting device package 101 can include a light-emitting device 130/130a (second light-emitting device) emitting light of one color (e.g., the first color or a blue color). As shown in FIG. 5, the second light-emitting device package 101 can include a second phosphor 150 that is excited by light emitted from the second light-emitting device 130 to emit light of a second color, and a third phosphor 160 that is excited by light emitted from the second light-emitting device 130 to emit light of a third color thereby emitting white light having a second color coordinate. This will be described in further detail below. In this way, the planar lighting device 200 can include the first light-emitting device package 100 and the second light-emitting device package 101 having different color coordinate settings. For example, the color reproducibility of the planar lighting device 200 can be improved using the first light-emitting device package 100, and the brightness of the planar lighting device 200 can be improved or the color coordinates can be adjusted using the second light-emitting device package 101. That is, the first light-emitting device package 100 can have a high color reproducibility with fixed color coordinates, and the second light-emitting device package 101 can have a high brightness or the color coordinates can be changed.

In more detail, the first light-emitting device package 100 can improve the color reproducibility of the planar lighting device 200, and the second light-emitting device package 101 can improve the brightness of the planar lighting device 200. In addition, the second light-emitting device package 101 can change the color coordinates of the planar lighting device 200 according to a target color coordinate. Accordingly, the color coordinate of white light emitted from the planar lighting device 200 can be adjusted according to a target color coordinate by using the first light-emitting device package 100 and the second light-emitting device package 101 having different color coordinate settings. Also, the planar lighting device 200 can be used in a display device 10 (see FIGS. 25 and 27) and express a target color coordinate. This will be described in detail below.

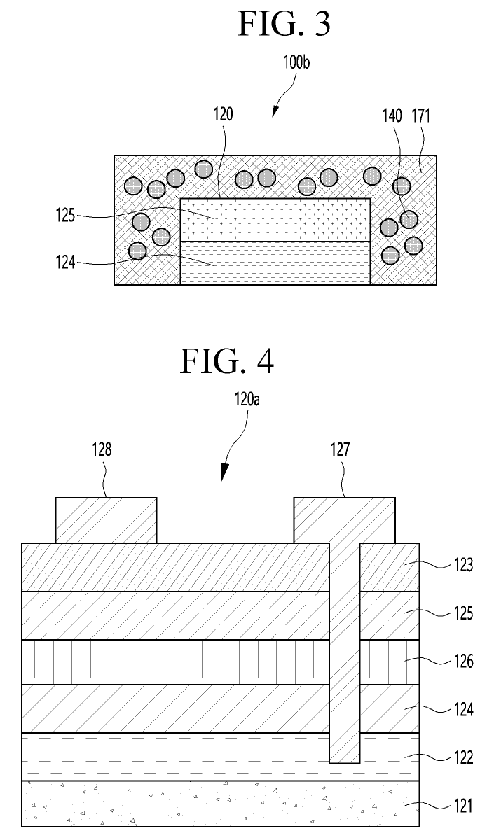

Next, FIGS. 2 and 3 are cross-sectional schematic diagrams illustrating examples of the first light-emitting device packages 100a and 100b applied to a planar lighting device according to a first embodiment of the present disclosure. In addition, FIG. 4 is a cross-sectional schematic diagram illustrating a first light-emitting device 120a applied to a planar lighting device according to the first embodiment. As shown in FIG. 2, the first light-emitting device package 100a can include the first light-emitting device 120 with a first light-emitting layer 124 emitting light of a first color having a first light-emitting wavelength band, and a second light-emitting layer 125 emitting light of a second color having a second light-emitting wavelength band, which are stacked. In addition, the first phosphor 140 converts light emitted from the first light-emitting device 120 to emit light of a third color having a third light-emitting wavelength band.

In more detail, as an example, the first color can be blue light, the second color can be green light, and the third color can be red light. Thus, the first light-emitting wavelength band can correspond to blue light, the second light-emitting wavelength band can correspond to green light, and the third wavelength band can correspond to red light. In this example, the positions of the first light-emitting layer 124 and the second light-emitting layer 125 can be interchanged. While FIGS. 2 to 4 illustrate an example in which the second light-emitting layer 125 is positioned over the first light-emitting layer 124, conversely, the first light-emitting layer 124 can be positioned over the second light-emitting layer 125.

Referring to FIG. 4, the first light-emitting layer 124 and the second light-emitting layer 125 represent active layers of the light-emitting device 120a having a multiple quantum well (MQL) structure. However, in FIGS. 2 and 3, the first light-emitting layer 124 and the second light-emitting layer 125 can each refer to a light-emitting unit having a multilayer structure emitting the first color and the second color. Referring to FIGS. 2 and 4, for example, the first light-emitting device package 100 in FIG. 1 can include the first light-emitting device package 100a including a package body 110 including a reflective cup 111 shape, a first light-emitting device 120 disposed within the package body 110, a first molding layer 170 covering the first light-emitting device 120 and disposed within the reflective cup shape 111, and the first phosphor 140 disposed within the first molding layer 170.

In this example, the first molding layer 170 can be formed using a resin material such as epoxy, silicone, or the like. Also, the first phosphor 140 can be provided in a powder form and dispersed within the first molding layer 170. In various examples, the package body 110 can include circuit lines, and the first light-emitting device 120 can be mounted within the package body 110 and electrically connected to the circuit lines. Also, the package body 110 can include a pad electrically connected to the outside.

Referring to FIGS. 3 and 4, the first light-emitting device package 100 can include a first light-emitting device package 100b as a chip scale package (CSP) having a second molding layer 171 and the first phosphor 140. Also, the first light-emitting device package 100b includes the second molding layer 171 coated on the outside of the first light-emitting device 120 and the first phosphor 140 dispersed within the second molding layer 171.

Again referring to FIG. 3, the second molding layer 171 having a predetermined thickness can be positioned on the outer surface of the light-emitting device 120 excluding the lower surface. Referring to FIG. 4, a cross-section of the first light-emitting device 120a according to an embodiment is schematically illustrated. As shown in FIG. 4, the first light-emitting device 120a can sequentially include a substrate 121, a first conductive type for example, N-type semiconductor layer 122, a first light-emitting layer 124, a barrier layer 126, a second light-emitting layer 125, and a second conductive type for example, P-type semiconductor layer 123.

In this example, the first conductive semiconductor layer 122 can include, for example, an N-type nitride semiconductor (N-GaN) layer while the second conductive semiconductor layer 123 can include, for example, a P-type nitride semiconductor (P-GaN) layer. Also, the barrier layer 126 can also include a nitride semiconductor as a conductive semiconductor layer. Further, the barrier layer 126 can include an N-type or P-type conductive semiconductor layer, or can include both N-type and P-type semiconductor layers.

Also, a first electrode 127 electrically connected to the first conductive semiconductor layer 122 can be positioned on one side of the second conductive semiconductor layer 123. In this situation, the first electrode 127 and the second conductive semiconductor layer 123 are insulated from each other, and the first electrode 127 can be connected to the first conductive semiconductor layer 122 by a structure such as a through hole. Also, a second electrode 128 electrically connected to the second conductive semiconductor layer 123 can be positioned on the other side of the second conductive semiconductor layer 123. As mentioned above, the positions of the first light-emitting layer 124 and the second light-emitting layer 125 can be interchanged. In this way, the first light-emitting device 120a can emit both first color light and second color light.

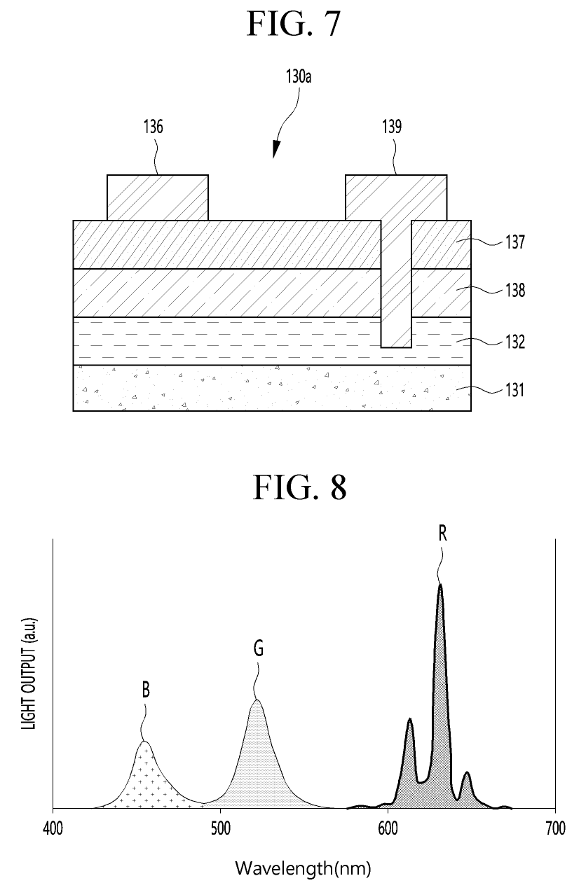

Next, FIG. 5 is a cross-sectional schematic diagram illustrating an example of the second light-emitting device package 101 applied to a planar lighting device according to the first embodiment of the present disclosure. In addition, FIGS. 6 and 7 are cross-sectional schematic diagrams showing examples of a second light-emitting device 130 a second light-emitting device 130a applied to a planar lighting device according to the first embodiment of the present disclosure. That is, FIG. 6 illustrates a horizontal light-emitting device 130, and FIG. 7 illustrates a flip-chip type light-emitting device 130a.

As shown in FIGS. 5 and 6, the second light-emitting device package 101 can include the second light-emitting device 130 including a third light-emitting layer 134 having a fourth light-emitting wavelength band emitting light of the first color, a second phosphor 150 having a fifth light-emitting wavelength band converted by light emitted from the second light-emitting device 130 to emit light of the second color, and the third phosphor 160 having a sixth wavelength band converted by light emitted from the second light-emitting device to emit light of the third color. The second light-emitting device package 101 can also include the second light-emitting device 130a including a third light-emitting layer 138 in the alternative example of FIG. 7. That is, FIG. 6 illustrates a horizontal light-emitting device 130, and FIG. 7 illustrates a flip-chip type light-emitting device 130a.

In the present example, the first color can be blue light, the second color can be green light, and the third color can be red light. In other words, the first light-emitting wavelength band can correspond to blue light, and the second light-emitting wavelength band can correspond to green light. Also, the third wavelength band can correspond to red light. The first phosphor 140 and the third phosphor 160 may include the same phosphor material. However, the first phosphor 140 and the third phosphor 160 can also include phosphors of different materials emitting light of the same color such that the emission peak of the spectrum of the first phosphor 140 and the emission peak of the spectrum of the second phosphor 150 can at least partially overlap.

Referring to FIG. 5 the second light-emitting device package 101can include the package body 110 including the reflective cup 111 shape, the second light-emitting device 130 positioned within the package body 110, the first molding layer 170 covering the second light-emitting device 130 and positioned within the reflective cup 111 shape, and the second phosphor 150 and the third phosphor 160 positioned within the first molding layer 170. In this example, the first molding layer 170 can be formed using a resin material such as epoxy, silicone, or the like. Also, the first phosphor 140 can be provided in a powder form and dispersed within the first molding layer 170. In various examples, the package body 110 can include circuit lines, and the first light-emitting device 120 can be mounted within the package body 110 and be electrically connected to these circuit lines. The package body 110 can also include pads electrically connected to the outside. A detailed description of this configuration is omitted.

Also, the second light-emitting device package 101 can be implemented in the form of a chip scale package (CSP) having the second molding layer 171 and the second phosphor 150 and the third phosphor 160, as shown in FIG. 3. Further, the second light-emitting device 130 in FIG. 5 used in the second light-emitting device package 101 can include a horizontal light-emitting device 130 as illustrated in FIG. 6 or a flip-chip type light-emitting device 130a as illustrated in FIG. 7.

Referring to FIG. 6, as an example used in the second light-emitting device package 101, the second light-emitting device 130 can emit blue light. Also, as shown, the second light-emitting device 130 can sequentially include a substrate 131, a first conductive type (e.g., N-type) semiconductor layer 132, a light-emitting layer 134, and a second conductive type (e.g., P-type) semiconductor layer 133 on a substrate 131. In this example, the first conductive type semiconductor layer 132 can include, for example, an N-type nitride semiconductor (N-GaN) layer while the second conductive type semiconductor layer 133 can include, for example, a P-type nitride semiconductor (P-GaN) layer. Also, the first conductive type semiconductor layer 132 can be partially opened, and a first electrode 135 can be positioned on the opening. Further, a second electrode 136 electrically connected to the second conductive semiconductor layer 133 can be positioned on the second conductive semiconductor layer 133.

Referring to FIG. 7, as another example used in the second light-emitting device package 101, the second light-emitting device 130a can emit blue light. In this example of the second light-emitting device 130a, a substrate 131, a first conductive (e.g., N-type) semiconductor layer 132, a light-emitting layer 138, and a second conductive (e.g., P-type) semiconductor layer 137 can be sequentially positioned. Also, a first electrode 139 electrically connected to the first conductive semiconductor layer 132 can be positioned on one side of the second conductive semiconductor layer 137. In this situation, the first electrode 139 and the second conductive semiconductor layer 137 can be insulated from each other, and the first electrode 139 can be connected to the first conductive semiconductor layer 132 by a structure such as a through hole while the second electrode 136 electrically connected to the second conductive semiconductor layer 137 can be positioned on the other side of the second conductive semiconductor layer 137.

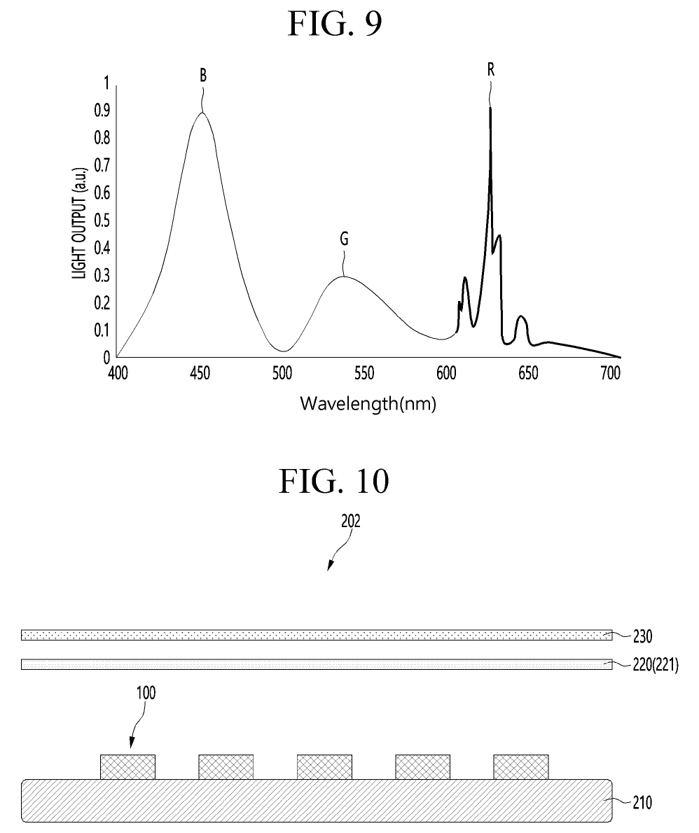

Next, FIG. 8 is a diagram showing the emission spectrum of a first light-emitting device package 100 applied to a planar lighting device according to a first embodiment of the present disclosure, and FIG. 9 is a diagram showing the emission spectrum of a second light-emitting device package 101 applied to a planar lighting device according to a first embodiment. As mentioned above, the planar lighting device 200 can include the first light-emitting device package 100 and the second light-emitting device package 101 having different color coordinate settings. For example, the first light-emitting device package 100 and the second light-emitting device package 101 can be arranged adjacent to each other on the wiring board 210. That is, the first light-emitting device package 100 and the second light-emitting device package 101 can be arranged alternately on the wiring board 210.

Referring to FIG. 8, the emission spectrum of the first light-emitting device package 100 is shown, in which light is emitted by the first light-emitting device 120 and the first phosphor 140. That is, the first light-emitting layer 124 emits light of the first color, the second light-emitting layer 125 emits light of the second color, and the first phosphor 140 emits light of the third color. Referring to FIG. 9, the emission spectrum of the second light-emitting device package 101 in which light is emitted by the third light-emitting layer 134 or 138 emitting light of the first color, the second phosphor 150 emitting light of the second color, and the third phosphor 160 emitting light of the third color is shown. Hereinafter, an example in which the first color is blue B, the second color is green G, and the third color is red R will be described. However, the present disclosure is not limited thereto.

As shown in FIGS. 8 and 9, the first light-emitting wavelength band and the fourth light-emitting wavelength band described above include main peaks, and the wavelength bands of the main peaks within the first light-emitting wavelength band and the fourth light-emitting wavelength band may at least partially overlap with each other. For example, the first light-emitting wavelength band of light emitted from the first light-emitting device package 100 and the fourth light-emitting wavelength band of light emitted from the second light-emitting device package 101 can correspond to blue light. Similarly, the second light-emitting wavelength band and the fifth light-emitting wavelength band include main peaks, respectively, and the wavelength bands of the main peaks within the second light-emitting wavelength band and the fifth light-emitting wavelength band can at least partially overlap with each other. For example, the second light-emitting wavelength band of the light emitted from the first light-emitting device package 100 and the fifth light-emitting wavelength band of the light emitted from the second light-emitting device package 101 may correspond to green light.

In addition, the third light-emitting wavelength band and the sixth light-emitting wavelength band described above include main peaks, respectively, and the wavelength bands of the main peaks within the third light-emitting wavelength band and the sixth light-emitting wavelength band can at least partially overlap with each other. For example, the third light-emitting wavelength band of the light emitted from the first light-emitting device package 100 and the sixth light-emitting wavelength band of the light emitted from the second light-emitting device package 101 may correspond to red light.

Referring to FIGS. 8 and 9, the full width at half maximum (FWHM) of the first color light B and the second color light G emitted from the first light-emitting device package 100 are different from the full width at half maximum (FWHM) of the first color light B and the second color light G emitted from the second light-emitting device package 101, respectively. For example, the full width at half maximum of the first color light B and the second color light G emitted from the first light-emitting device package 100 can be smaller than the full width at half maximum of the first color light B and the second color light G emitted from the second light-emitting device package 101, respectively.

Meanwhile, there may not be a significant difference in half-width between the third color light R emitted from the first light-emitting device package 100 and the third color light R emitted from the second light-emitting device package 101. In this way, the half-width of the main peak of the emission spectrum emitted from the first light-emitting device package 100 can be relatively small. Thus, the color purity of the emission spectrum emitted from the first light-emitting device package 100 can be improved. Accordingly, the color purity of the white light emitted from the first light-emitting device package 100 can be improved, and the color reproducibility of the planar lighting device 200 including the light-emitting device package 100 can be further improved.

As shown in FIGS. 8 and 9, the emission peak of the spectrum of the first light-emitting wavelength band of light emitted from the first light-emitting device package 100 can be located within the emission peak of the spectrum of the fourth light-emitting wavelength band of light emitted from the second light-emitting device package 101 (see also FIG. 21). Also, the intensity of the spectrum of the first light-emitting wavelength band of light emitted from the second light-emitting device package 101 can be less than the intensity of the spectrum of the fourth light-emitting wavelength band of light emitted from the second light-emitting device package 101 (see FIG. 21). Further, the emission peak of the spectrum of the second light-emitting wavelength band of light emitted from the first light-emitting device package 100 can be located within the emission peak of the spectrum of the fifth light-emitting wavelength band of light emitted from the second light-emitting device package 101 (see also FIG. 21). Still further, intensity of the spectrum of the second light-emitting wavelength band of the light emitted from the second light-emitting device package 101 can be less than the intensity of the spectrum of the fifth light-emitting wavelength band of the light emitted from the second light-emitting device package 101 (see also FIG. 21).

Next, FIG. 10 is a conceptual diagram of a planar lighting device 202 according to a second embodiment of the present disclosure. Referring to FIG. 10, the planar lighting device 202 can include the wiring board 210, the light source including the first light-emitting device packages 100 arranged and positioned on the wiring board 210, and the light diffusion layer 220 (221) positioned on the light source. In the present example, the light diffusion layer 220 (221) can be implemented as the light diffusion plate 220 or the light guide plate 221 depending on the shape of the backlight unit 200. Further, , the optical sheet 230 can be positioned on one side of the light diffusion layer 220 (221). For example, the light diffusion layer 220 (221) can be positioned between the wiring board 210 and the optical sheet 230, the optical sheet 230 can include a plurality of layers having optical functions, and the first light-emitting device package 100 can be arranged and provided on the wiring board 210. Also, the light-emitting device packages 100 can emit white light, and the light-emitting device packages 100 can be positioned at regular intervals on the wiring board 210.

In various examples, the wiring board 210 can include connection wiring electrically connected to the first light-emitting device packages 100. For example, at least some of the first light-emitting device packages 100 can be individually driven by the connection of such connection wiring. Also, the light sources can be driven simultaneously, or can be driven differently by each region. This type of driving in which the light sources are driven differently by each region can be referred to as local dimming driving. A detailed description thereof will be omitted herein.

In addition, the first light-emitting device package 100 can include a stacked light-emitting device 120 (a first light-emitting device; see FIG. 2) having two light-emitting layers 124 and 125 (see FIG. 4). Thus, the first light-emitting device package 100 can emit white light having the first color coordinate by including the first light-emitting device 120 and a phosphor 140 (first phosphor; see FIG. 2) excited by light emitted from the first light-emitting device 120. Also, the color reproducibility of the planar lighting device 200 can be improved by using the first light-emitting device package 100. The planar lighting device 200 can be used in the display device 10 of FIGS. 25 and 27 to express a target color coordinate.

In addition, the second embodiment can implement a planar lighting device 202 (FIG. 10) by using the first light-emitting device packages 100. In this way, the color purity of white light emitted from the first light-emitting device package 100 can be improved, and the color reproducibility of the planar lighting device 202 including the light-emitting device package 100 can be further improved. The same description as described in the first embodiment above can be applied to other parts not described. Therefore, redundant descriptions are omitted.

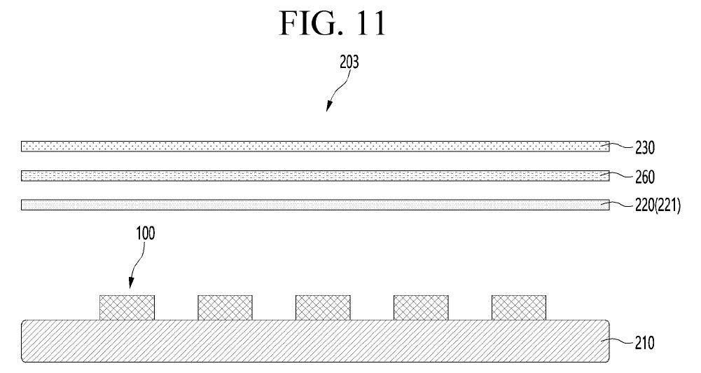

Next, FIG. 11 is a conceptual diagram of a planar lighting device 203 according to a third embodiment of the present disclosure. Referring to FIG. 11, the planar lighting device 203 can include the wiring board 210, the light source including the first light-emitting device packages 100 arranged and positioned on the wiring board 210, and the light diffusion layer 220 (221) positioned on the light source. Further, an optical sheet 230 can be positioned on one side of the light diffusion layer 220 (221) such that the light diffusion layer 220 (221) can be positioned between the wiring board 210 and the optical sheet 230. Also, the optical sheet 230 can include a plurality of layers having optical functions.

Still further, a color-coordinated sheet 260 capable of controlling the color coordinates of light emitted from the first light-emitting device package 100 can be further provided on one side of the light diffusion layer 220 (221) or one side of the optical sheet 230. In various examples, the light emitted from the first light-emitting device package 100 can have a fixed color coordinate, and the fixed color coordinates can be controlled by the color-coordinated sheet 260. Also, the color-coordinated sheet 260 can be positioned between the light diffusion layer 220 (221) and the optical sheet 230. Parts not described above can be equally applied to the first or second embodiment. Therefore, redundant descriptions will be omitted.

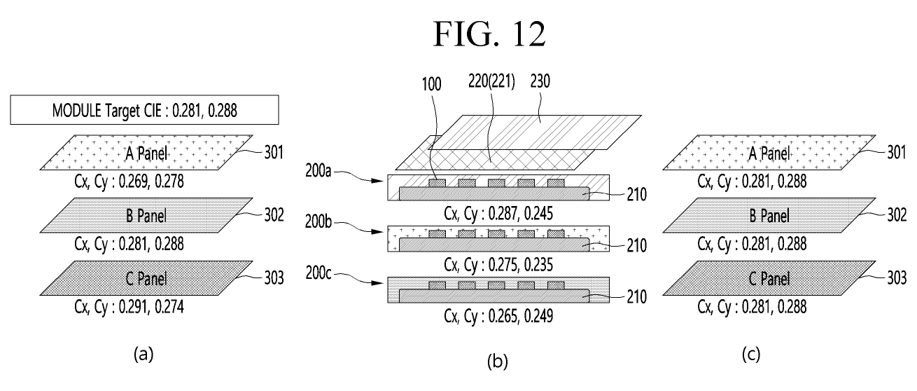

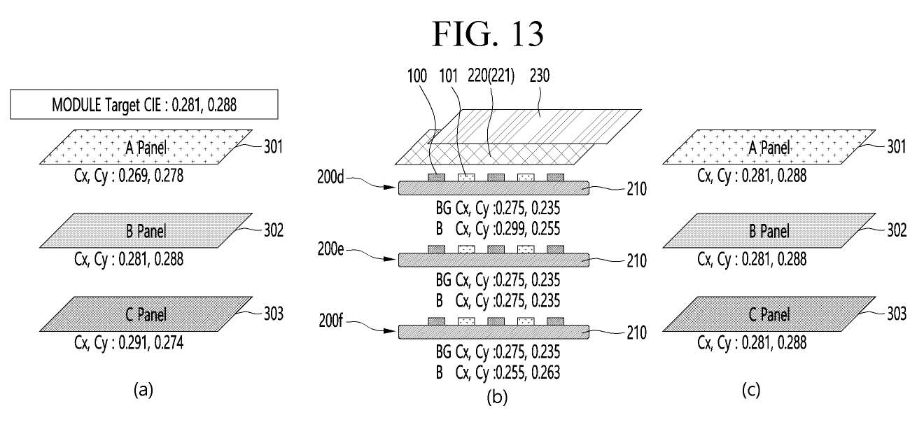

Next, FIG. 12 is a schematic diagram illustrating a process of tuning a target color coordinate of the display device using the planar lighting device according to the second or third embodiment of the present disclosure. Also, FIG. 13 is a schematic diagram illustrating a process of tuning a target color coordinate of the display device using the planar lighting device according to the first embodiment of the present disclosure. As described above, the display device 10 or 11 (see FIGS. 25 and 27) can be manufactured using planar lighting devices 200, 202, or 203. First, referring to FIG. 12, a process of tuning a target color coordinate of a display device using a planar lighting device according to the second or third embodiment will be described.

The display device 10 or 11 according to one embodiment can include a liquid crystal display panel 300 having the planar lighting device 202 or 203 emitting white light and a color conversion filter 310 (see, e.g., FIGS. 25 and 27) positioned on the planar lighting device 202 or 203 and converting the white light of the planar lighting device 200. In this instance, the planar lighting device 200 can include the light source including the first light-emitting device packages 100 constituting a white light source. By implementing the planar lighting device 202 or 203 using the first light-emitting device package 100, the color reproducibility can be improved compared to using a light-emitting device package that uses a blue light-emitting device and green and red phosphors. Also, using the first light-emitting device package 100 as described above, the color coordinates of white light emitted from the planar lighting device 200 can be adjusted according to a target color coordinate. Further, the planar lighting device 200 can be used in the display device 10 (see FIGS. 25 and 27) to express a target color coordinate.

In more detail, referring to the example of FIG. 12(a) the target color coordinates target CIE of a display module in which the planar lighting device 200 and the display panel 300 are combined can be set. Assuming the display device 10 and 11 including the display module has a uniform color coordinate and the target color coordinate (Cx, Cy) is (0.281, 0.288) (Cx, Cy: 0.281, 0.288), there can be differences in the color coordinates of each panel. For example,, the color coordinates of A Panel 301 can be (Cx, Cy: 0.269, 0.278), the color coordinates of B Panel 302 can be (Cx, Cy: 0.281, 0.288), and the color coordinates of C Panel 303 can be (Cx, Cy: 0.291, 0.274), which can be different from each other. However, as described above, excellent color reproducibility can be realized using the first light-emitting device package 100. In this example, the color coordinates of the light emitted from the first light-emitting device package 100 can be fixed according to the first light-emitting device 120. Also, the first light-emitting device package 100 can have a constant wavelength band since light of the first color (e.g., blue) and light of the second color (e.g., green) are emitted from the light-emitting layer of the first light-emitting device 120. Accordingly, in order to achieve a target color coordinate, the first light-emitting device packages 100 emitting light of different color coordinates can be used in combination with panels 301, 302 and 303 having different color coordinates.

Referring to FIG. 12(b), different first light-emitting device packages 100 emitting light of which at least some have different color coordinates can be used. For example, in the first planar lighting device 200a, light emitted from the first light-emitting device package 100 can have a color coordinate of (Cx, Cy: 0.287, 0.245), in the second planar lighting device 200b, light emitted from the first light-emitting device package 100 can have a color coordinate of (Cx, Cy: 0.275, 0.235), and in the third planar lighting device 200c, light emitted from the first light-emitting device package 100 can have a color coordinate of (Cx, Cy: 0.265, 0.249). By selectively combining light from different first light-emitting device packages 100, at least some of which emit light having different color coordinates, can be used to change tune corresponding to each panel 301, 302, or 303 in FIG. 12(c). As is shown in FIG. 12(c), the same target color coordinates (Cx, Cy; 0.281, 0.288) can be implemented in each display device combining each panel 301, 302, or 303 and each planar lighting device 200a, 200b, or 200c. In this way, the color reproducibility of the display device 10 using the planar lighting device backlight unit; 200 can be improved to the level of a self-luminous display device, while target color coordinates of each of the display device 10 and 11 can be implemented. In addition, the brightness of the display device 10 can be maintained or improved.

Next, referring to FIGS. 13(a)-13(c), a process of tuning the target color coordinates of the display device using the planar lighting device according to the first embodiment will be described. The display device 10 and 11 according to one embodiment can be configured to include the liquid crystal display panel 300 having the planar lighting device 200 emitting white light and the color conversion filter 310 (see, e.g., FIGS. 25 and 27) positioned on the planar lighting device 200 and converting the white light of the planar lighting device 200. In this situation, the planar lighting device 200 can include the light source including the first light-emitting device packages 100 and the second light-emitting device packages 101 constituting a white light source.

As described above, the first light-emitting device package 100 can improve the color reproducibility of the planar lighting device 200 or the display device 10 and 11. Similarly, the second light-emitting device package 101 can be configured to improve the brightness of the planar lighting device 200 or the display device 10 and 11. In addition, the second light-emitting device package 101 can be configured to change the color coordinates of the planar lighting device 200 or the display device 10 and 11 according to a target color coordinate. Specifically, by using the first light-emitting device package 100 and the second light-emitting device package 101 having such different color coordinate settings, the color coordinates of white light emitted from the planar lighting device 200 can be adjusted according to target color coordinates. Also, such a planar lighting device 200 can be implemented to be used in the display device 10 and 11 (see, e.g., FIGS. 25 and 27) so the display device 10 and 11 expresses the target color coordinates.

First, referring FIG. 13(a), a target color coordinate target CIE of the display module in which the planar lighting device 200 and the display panel 300 are combined can be set. The display device 10 and 11 including the display module can be set to have uniform color coordinates. In the present example, the target color coordinates (Cx, Cy) can be (0.281, 0.288) (Cx, Cy: 0.281, 0.288). In this example, a difference can occur in the color coordinates of each panel. For example, referring to FIG. 13(a), the color coordinates of A Panel 301 can be (Cx, Cy: 0.269, 0.278), the color coordinates of the B Panel 302 can be (Cx, Cy: 0.281, 0.288), and the color coordinates of the C Panel 303 can be (Cx, Cy: 0.291, 0.274).

As described above, excellent color reproducibility can be realized using the first light-emitting device package 100, but the first light-emitting device package 100 can be fixed. The first light-emitting device package 100 can have a constant wavelength band since light of the first color (e.g., blue) and light of the second color (e.g., green) are emitted from the light-emitting layer of the first light-emitting device 120. Also, the second light-emitting device package 101 can be capable of changing tuning the color coordinates. Because the second color light emitted from the second light-emitting device package 101 is emitted by the second phosphor 150, the color coordinates of the light can be changed using the second light-emitting device package 101.

Referring to FIG. 13(b), the color coordinates of white light emitted from the first light-emitting device package 100 represented by BG can be fixed at (Cx, Cy: 0.275, 0.235). However, the light emitted from the second light-emitting device package 101 represented by B can have different values in each panel in order to implement the target color coordinates. For example, in the first planar lighting device 200d, the light emitted from the second light-emitting device package 101 can have a color coordinate of (Cx, Cy: 0.299, 0.255), in the second planar lighting device 200e, the light emitted from the second light-emitting device package 101 can have a color coordinate of (Cx, Cy: 0.275, 0.235), and in the third planar lighting device 200f, the light emitted from the second light-emitting device package 101 can have a color coordinate of (Cx, Cy: 0.255, 0.265). Using this combination, the color coordinate of the light emitted from the second light-emitting device package 101 can be changed for each panel 301, 302, and 303. For example, while the light emitted from the light-emitting device 120 and 130 has a fixed color coordinate, the phosphor 140 and 150 converting the light emitted from the light-emitting device 120 and 130 can be changed according to the content, material, and the like. For example, for the second type of the second light-emitting device package 101, a content of at least one of the light body 150 or the third phosphor 160 can be adjusted according to the transmission spectrum of the color conversion filter 310 of the display device 10 and 11. Also, the second phosphor 150 can have a first content to have a target color coordinate value of the liquid crystal display panel 300. Similarly, the third phosphor 160 can have a second content to have a target color coordinate value of the liquid crystal display panel 300.

Accordingly, referring to FIG. 13(c), the same target color coordinate (Cx, Cy; 0.281, 0.288) can be implemented in each display device combining each panel 301, 302 and 303 and each planar lighting device 200d, 200e and 200f. In this way, the color reproducibility of the display device 10 and 11 using the planar lighting device (backlight unit) 200 can be improved to the level of a self-luminous display device, while the target color coordinates of each display device 10 and 11 can be implemented. In addition, the brightness of the display device 10 and 11 can be maintained or improved. Also, since the shift in the color coordinate according to the current of the second light-emitting device package 101 tends to be smaller than the shift in the color coordinate according to the current of the first light-emitting device package 100, the color change rate according to the driving current can be reduced by configuring the first light-emitting device package 100 and the second light-emitting device package 101 together in the planar lighting device 200.

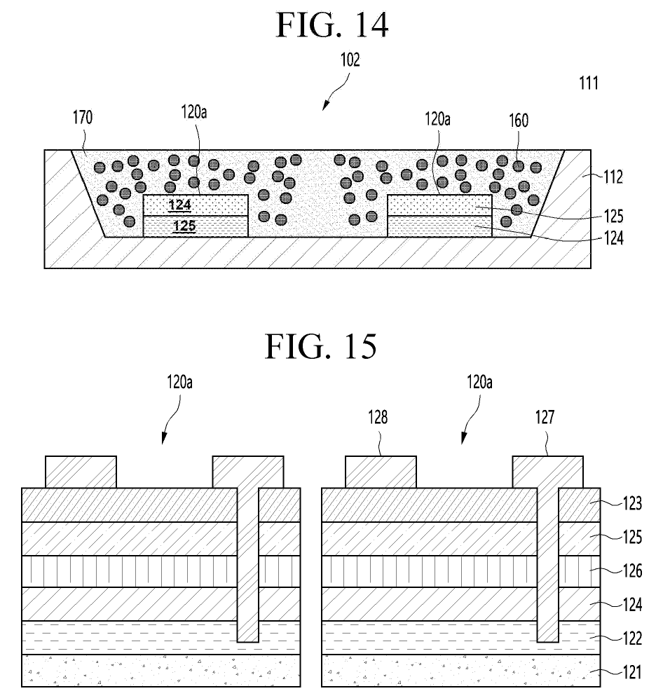

Next, FIGS. 14 to 19 depict cross-sectional schematic diagrams illustrating other embodiments of the first light-emitting device package applied to the planar lighting device according to the embodiments of the present disclosure. In particular, FIGS. 14, 16, and 18 illustrate varying embodiments of the first light-emitting device package, and FIGS. 15, 17, and 19 illustrate implementation examples of the first light-emitting device used in these first light-emitting device packages. Referring to FIG. 14, an example of a first light-emitting device package 102 including a plurality of light-emitting devices 120a (first light-emitting devices) is illustrated. In this example, the first light-emitting device package 102 can include two adjacent light-emitting devices 120a referred to as the first-1 light-emitting device and the first-2 light-emitting device, respectively. As described above, the first light-emitting device 120a can include the first light-emitting layer 124 that is provided in a stacked manner emitting light of a first wavelength band of the first color, and the second light-emitting layer 125 having emitting light of a second wavelength band of the second color. In the present example, the positions of the first light-emitting layer 124 and the second light-emitting layer 125 may be interchanged.

Referring to the example of FIGS. 14 and 15, the two light-emitting devices 120a having the same position of the first light-emitting layer 124 and the second light-emitting layer 125 can be positioned adjacent to each other. In the light-emitting device 120a, the second light-emitting layer 125 can be positioned on the first light-emitting layer 124. Also, the first light-emitting device package 102 can include the package body 110 including the reflective cup 111 shape, two first light-emitting devices 120a positioned adjacent to each other within the package body 110, the first molding layer 170 covering the first light-emitting devices 120a and positioned within the reflective cup shape 111, and the first phosphor 140 positioned within the first molding layer 170.

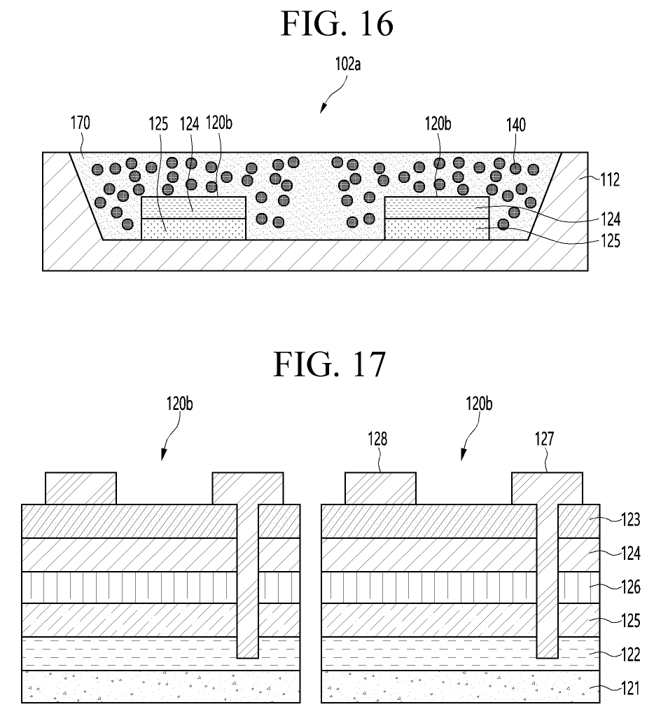

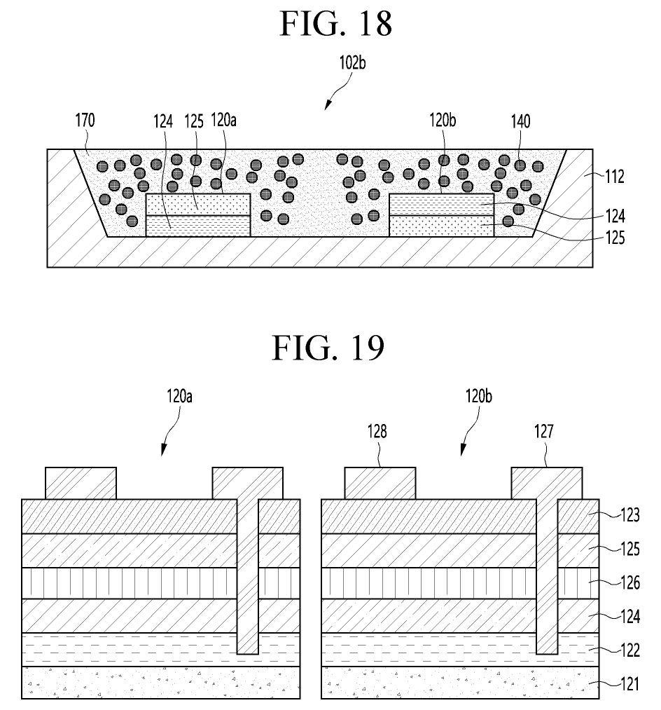

Referring to FIG. 16, another example of the first light-emitting device package 102a including the light-emitting devices 120b (first light-emitting devices) is shown. Referring to FIG. 17, two light-emitting devices 120b having the same positions of the first light-emitting layer 124 and the second light-emitting layer 125 can be positioned adjacent to each other. As shown, the light-emitting device 120b can have the first light-emitting layer 124 positioned on the second light-emitting layer 125. Referring to FIGS. 18 and 19, two light-emitting devices 120a and 120b having different positions of the first light-emitting layer 124 and the second light-emitting layer 125 can be positioned adjacent to each other in the first light-emitting device package 102b. In this example, the light-emitting device 120a having the second light-emitting layer 125 positioned on the first light-emitting layer 124 and the light-emitting device 120b having the first light-emitting layer 124 positioned on the second light-emitting layer 125 can be positioned adjacent to each other in the first light-emitting device package 102b.

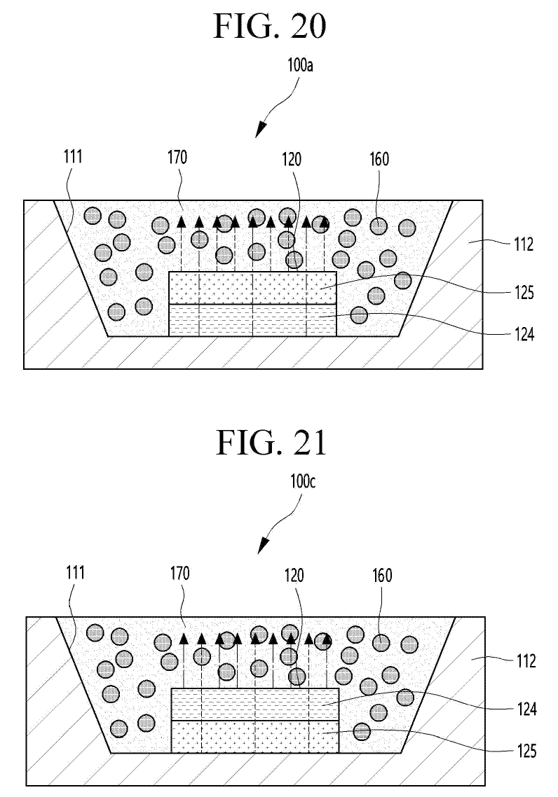

Next, FIGS. 20 and 21 are diagrams illustrating differences according to the stacking order of the first light-emitting device package applied to the planar lighting device according to embodiments of the present disclosure. In particular, FIG. 20 shows an example of the light-emitting device package 100a including the light-emitting device 120 with the second light-emitting layer 125 positioned on the first light-emitting layer 124, and FIG. 21 shows an example of the light-emitting device package 100c including the light-emitting device 120 with the first light-emitting layer 124 positioned on the second light-emitting layer 125. Among these light-emitting device packages 100a and 100c, when the first light-emitting layer 125 emitting light of the first color (e.g., blue) is positioned on the upper side, as in the example of FIG. 20, light corresponding to the second color (e.g., green) can have a relatively low light quantity because it passes through the first light-emitting layer 125. Accordingly, the intensity of the green light can be weakened, resulting in a relatively low color reproducibility. On the other hand, since blue light is directly emitted and has relatively high energy exciting the first phosphor 140, high brightness can be achieved. Also, when the second light-emitting layer 124 emitting light of a second color e.g., green is positioned on the upper side, as in the example of FIG. 21, light corresponding to the first color (e.g., blue) can have relatively weaker energy to excite the first phosphor 140 because it passes through the second light-emitting layer 124. On the other hand, green light can be directly emitted, thereby increasing color reproducibility. In the planar lighting device 200 according to embodiments, light-emitting device packages 100a and 100c having such different arrangements of light-emitting layers 124 and 125 can be selectively used.

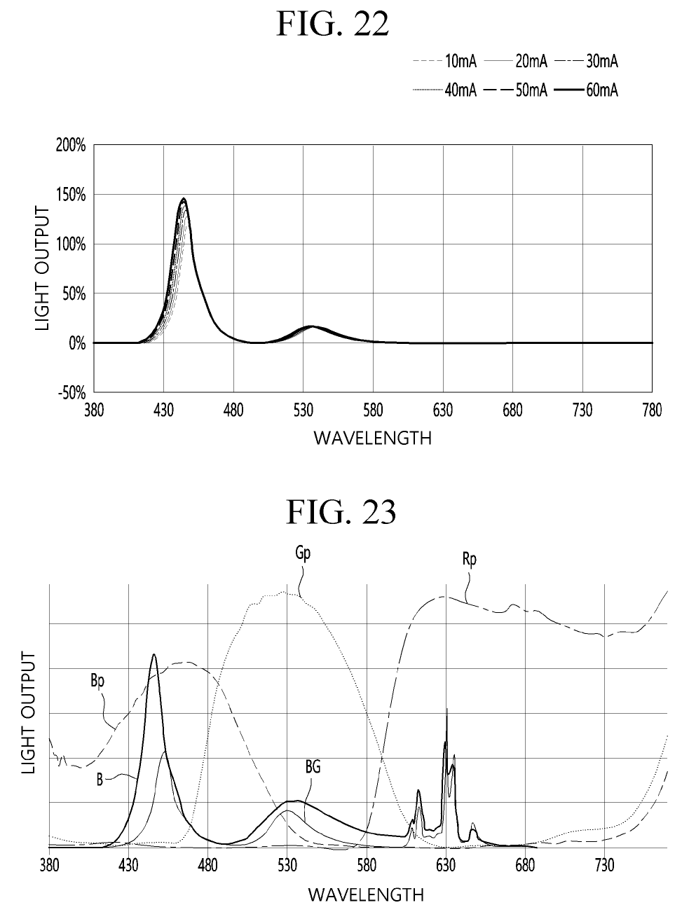

Next, FIG. 22 is a diagram illustrating a wavelength change according to a driving current of the first light-emitting device package applied to the planar lighting device according to various embodiments of the present disclosure. As mentioned above, when the planar lighting device 200 is used in the display device 10 and 11, the wavelength of light in some wavelength bands can shift due to varying current varying. For example, the wavelength shift according to the current of the first light-emitting device 120 in the first light-emitting device package 100 can be greater than the wavelength shift of the second light-emitting device 130 applied to the second light-emitting device package 101. As such, the shift in color coordinates according to the current of the second light-emitting device package 101 tends to be smaller than the shift in color coordinates according to the current of the first light-emitting device package 100. Therefore, by configuring the planar lighting device 200 with the first light-emitting device package 100 and the second light-emitting device package 101, the color change rate according to the driving current can be reduced.

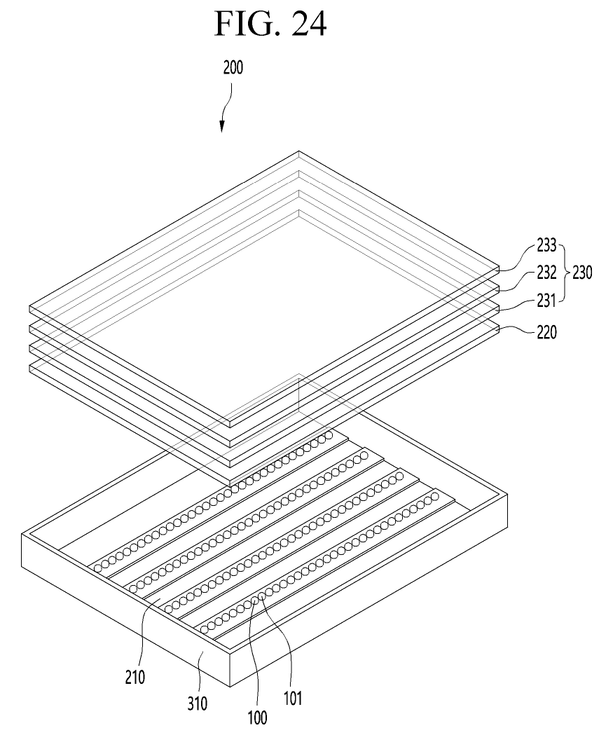

Next, FIG. 23 is a diagram illustrating the emission spectrum of the display device according to the embodiments. In particular, FIG. 23 shows the spectrum of light emitted from the example display devices 10 and 11. In FIG. 23, the upper portion shows the transmission region of the panel 300. For example, the transmission wavelength band by the color conversion filter (color filter 310) of the panel 300 is shown. The line labeled “Bp” represents the transmission wavelength band by the blue filter, the line labeled “Gp” represents the transmission wavelength band by the green filter, and the line labeled “Rp” represents the transmission wavelength band by the red filter. Also, the spectrum indicated by the line labeled “BG” represents the emission spectrum of the first light-emitting device package 100, and the spectrum indicated by the line “B” represents the emission spectrum of the second light-emitting device package 101.

Also, all colors can be expressed using the three primary colors of red R, green G, and blue B. When red R, green G, and blue B light are mixed, white light is created, and when white light passes through a color conversion filter (e.g., color filter 310 in FIG. 24), any color can be produced. Therefore, when a color filter with a high transmittance for a wavelength corresponding to a particular color interacts with an input light source, a magnitude of the output light can be a value obtained by multiplying the area corresponding to the wavelength of the color filter by the input light source. In the present example, output light is distinguished by color, and the higher the transmittance value, the more accurately the colors are expressed without mixing. To this end, it is desirable for the color filter to clearly distinguish and pass light without mixing with other colors, and it is advantageous to use a light source with clearly distinguished output wavelengths of red R, green G, and blue B. Therefore, as described above, by using the first light-emitting device package 100 in which the wavelengths of red R, green G, and blue B light are relatively clearly distinguished, high-output, high-purity colors matched by respective color filters can be realized. Also, by using the second light-emitting device package 101 in combination with a relatively high light intensity, color coordinate tuning is possible, and wavelength shift according to current is relatively small, the target color coordinates of each display device 10 and 11 can be easily realized.

Next, FIGS. 24 and 25 are diagrams illustrating a display device according to a first embodiment of the present disclosure. Referring to FIGS. 24 and 25, an example of the display device 10 including the direct-type planar lighting device 200 using the first light-emitting device package 100 and the second light-emitting device package 101 according to the first embodiment described above as a light source is shown. The present example of FIG. 25 having the above-described the planar lighting device 200 is a liquid crystal display device 10. As is shown in FIG. 25, the liquid crystal display device 10 can have the planar lighting device 200 positioned on a lower cover 340. This planar lighting device 200 can include the first light-emitting device package 100 and the second light-emitting device package 101 according to embodiments. FIGS. 24 and 25 show an example of the planar lighting device 200 using the first light-emitting device package 100 and the second light-emitting device package 101 according to the first embodiment as a light source with the planar lighting device 200 implemented using the first light-emitting device package 100 as a light source.

As is shown in FIGS. 24 and 25, the light diffuser plate 220 described above can be positioned on the light source, and an optical sheet 230 can be provided on the light diffuser plate 220. In the present example, the optical sheet 230 can include a plurality of functional films 231, 232, and 233. Also, a reflective sheet 250 can be positioned between the planar lighting device 200 and the lower cover 340 while a liquid crystal display panel 300 can be positioned on the planar lighting device 200. Additionally, the liquid crystal display panel 300 can be supported by a mold frame 330, and the upper cover 320 can be positioned on a mold frame 330. In various examples, the liquid crystal display panel 300 can include a liquid crystal layer, a color conversion filter color filter; 310, a polarizing sheet, and the like.

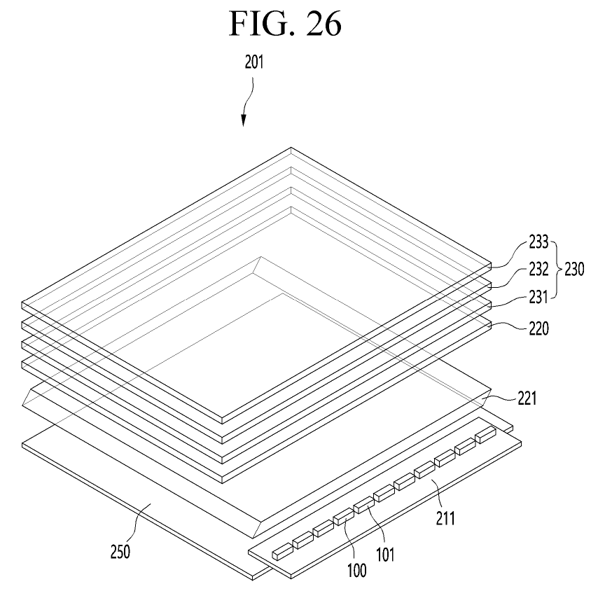

Next, FIGS. 26 and 27 are diagrams illustrating a display device according to a second embodiment. Referring to FIGS. 26 and 27, an example of the display device 11 including an edge-type planar lighting device 201 using the first light-emitting device package 100 and the second light-emitting device package 101 according to the first embodiment described above as a light source is illustrated. An example of the display device 11 including the planar lighting device 201 can be the liquid crystal display device 10. The edge-type planar lighting device 201 can diffuse light using the light guide plate 221. The optical sheet 230 can be provided on the light guide plate 221. In the present example, the optical sheet 230 can include the functional films 231, 232, and 233.

In addition, the liquid crystal display device 11 can have the planar lighting device 201 positioned on the lower cover 340. The planar lighting device 201 can include the first light-emitting device package 100 and the second light-emitting device package 101 according to embodiments of the present disclosure. FIGS. 26 and 27 illustrate a planar lighting device 201 using the first light-emitting device package 100 and the second light-emitting device package 101 according to the first embodiment as a light source. Meanwhile, a planar lighting device 201 can be implemented using the first light-emitting device package 100 as a light source.

Further, the reflective sheet 250 can be positioned between the planar lighting device 201 and the lower cover 340. The liquid crystal display panel 300 can be positioned on the planar lighting device 201. In addition, the liquid crystal display panel 300 can be supported by the mold frame 330. The upper cover 320 can be positioned on the mold frame 330. A heat bar 270 can be positioned on one side of the mold frame 330, and a wiring board 211 can be positioned on the heat bar 270. Light can be irradiated from the light source toward the light guide plate 221. In various examples, the liquid crystal display panel 300 can include a liquid crystal layer, a color conversion filter color filter 310, a polarizing sheet, and the like.

The features, structures, effects, and the like described in the embodiments above are included in at least one embodiment of the present disclosure, and are not necessarily limited to merely one embodiment. Furthermore, the features, structures, effects, and the like exemplified in each embodiment can be combined or modified to implement other embodiments by those skilled in the art to which the embodiments pertain. Therefore, it should be construed such combinations and modifications fall within the scope of the present disclosure.

Furthermore, while the embodiments have been described above, these are merely examples and do not limit the present disclosure. Those skilled in the art will appreciate various modifications and applications not exemplified above are possible without departing from the characteristics of the embodiments. For example, each component specifically illustrated in the embodiments can be modified and implemented. And the differences related to these modifications and applications should be construed as being included within the scope of the present disclosure as defined in the appended claims.

What is claimed is:

1. A planar lighting device comprising:
a wiring board;
a light source including a plurality of first light-emitting device packages and a plurality of second light-emitting device packages alternately disposed on the wiring board; and
a light diffusion layer disposed on the light source,
wherein the first light-emitting device package emits first white light having a first color coordinate and includes:
a first light-emitting device including a stacked first light-emitting layer emitting light of a first color and a second light-emitting layer emitting light of a second color; and
a first phosphor converting light emitted from the first light-emitting device to emit light of a third color, and
wherein the second light-emitting device package emits second white light having a second color coordinate different than the first color coordinate and includes:
a second light-emitting device including a third light-emitting layer emitting light of the first color;
a second phosphor converting light emitted from the second light-emitting device to emit light of the second color; and
a third phosphor converting light emitted from the second light-emitting device to emit light of the third color.

2. The planar lighting device of claim 1, wherein the light of the first color emitted by the first light-emitting device has a first light-emitting wavelength band, the light of the second color emitted by the first light-emitting device has a second light-emitting wavelength band, and the light emitted by the first light-emitting device and converted by the first phosphor has a third light-emitting wavelength band, and
wherein the light of the first color emitted by the second light-emitting device has a fourth light-emitting wavelength band, the light emitted by the second light-emitting device and converted by the first phosphor has a fifth light-emitting wavelength band, and the light emitted by the second light-emitting device and converted by the second phosphor has a sixth light-emitting wavelength band.

3. The planar lighting device of claim 2, wherein the first light-emitting wavelength band has a half-width of spectrum narrower than a half-width of spectrum of the fourth light-emitting wavelength band.

4. The planar lighting device of claim 3, wherein an intensity of spectrum of the first light-emitting wavelength band is smaller than an intensity of spectrum of the fourth light-emitting wavelength band.

5. The planar lighting device of claim 4, wherein a half-width of spectrum of the fifth light-emitting wavelength band is narrower than a half-width of spectrum of the second light-emitting wavelength band.

6. The planar lighting device of claim 1, wherein an intensity of spectrum of the fifth light-emitting wavelength band is smaller than an intensity of spectrum of the second light-emitting wavelength band.

7. The planar lighting device of claim 1, wherein the first light-emitting device package and the second light-emitting device package have different color coordinate settings.

8. The planar lighting device of claim 1, wherein the first light-emitting device package and the second light-emitting device package are disposed adjacent to each other.

9. The planar lighting device of claim 1, wherein a shift in a color coordinate of the second light-emitting device package according to current is smaller than a shift in a color coordinate of the first light-emitting device package according to current.

10. The planar lighting device of claim 1, wherein the first light-emitting device package includes a first-1 light-emitting device and a first-2 light-emitting device that are adjacent to each other.

11. The planar lighting device of claim 10, wherein the first-1 light-emitting device and the first-2 light-emitting device have different stacking orders of the first light-emitting layer and the second light-emitting layer.

12. A display device comprising:
a planar lighting device emitting white light; and a liquid crystal display panel disposed on the planar lighting device and having a color conversion filter for converting the white light of the planar lighting device, the planar lighting device comprising:
a light source including a plurality of first light-emitting device packages and a plurality of second light-emitting device packages constituting a white light source; and
a light diffusion layer disposed on the light source,
wherein the first light-emitting device package includes:
a first light-emitting device including a first light-emitting layer having a first light-emitting wavelength band that emits light of a first color and a second light-emitting layer having a second light-emitting wavelength band that emits light of a second color; and a first phosphor having a third light-emitting wavelength band converted by light emitted from the first light-emitting device to emit light of a third color, and
wherein the second light-emitting device package includes:
a second phosphor having a fifth light-emitting wavelength band converted by light emitted from the second light-emitting device to emit light of the second color; and a third phosphor having a sixth light-emitting wavelength band converted by light emitted from the second light-emitting device to emit light of the third color.

13. The display device of claim 12, wherein a content of at least one of the second phosphor or the third phosphor of the second light-emitting device package is adjusted according to a transmission spectrum of the color conversion filter.

14. The display device of claim 12, wherein the second phosphor has a first content to have a target color coordinate value of the liquid crystal display panel.

15. The display device of claim 12, wherein the third phosphor has a second content to have a target color coordinate value of the liquid crystal display panel.

16. The display device of claim 12, wherein the first light-emitting device package and the second light-emitting device package are disposed adjacent to each other.

17. The display device of claim 12, wherein a half-width of spectrum of the first wavelength band is narrower than a half-width of spectrum of the fourth wavelength band.

18. The display device of claim 12, wherein an intensity of spectrum of the first wavelength band is smaller than an intensity of spectrum of the fourth wavelength band.

19. The display device of claim 12, wherein a half-width of spectrum of the fifth wavelength band is narrower than a half-width of spectrum of the second wavelength band.

20. The display device of claim 12, wherein an intensity of spectrum of the fifth wavelength band is smaller than an intensity of spectrum of the second wavelength band.

21. A display device comprising:
a planar lighting device emitting white light; and
a liquid crystal display panel disposed on the planar lighting device and having a color conversion filter for converting the white light of the planar lighting device,
wherein the planar lighting device includes:
a light source including a plurality of light-emitting device packages constituting a white light source; and
a light diffusion layer disposed on the light source,
wherein at least one of the light-emitting device packages includes:
a first light-emitting device comprising a semiconductor and including a first light-emitting layer emitting light of a first wavelength band of a first color and a second light-emitting layer emitting light of a second wavelength band a second color different than the first color; and
a first phosphor converting light emitted from the first light-emitting device to a third wavelength band of a third color different than the first color and the second color; and
wherein at least another of the light-emitting device packages includes:
another light-emitting device emitting light of the first color; and
a second phosphor converting light from the another light-emitting device to the second color; and
a third phosphor converting light from the another light-emitting device to the third color.
